(19) United States
(12) Patent Application Publication
(10) Pub. No.: US 2008/0225468 A1
(43) Pub. Date: Sep. 18, 2008

(54) HOUSING FOR PORTABLE ELECTRONIC DEVICE

(75) Inventors: WEI HUANG, Shenzhen (CN); RUI-KUN HUANG, Shenzhen (CN); YUN-QIAN WANG, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 11/840,224

(22) Filed: Aug. 17, 2007

(30) Foreign Application Priority Data
Mar. 14, 2007 (CN) 200710200280.0

(51) Int. Cl. H05K 7/00

(52) U.S. Cl. 361/679

(57) ABSTRACT

An exemplary housing (100) for portable electronic device includes a main structure (10) and a static electricity eliminating structure (18). The main structure includes a top cover (12), a bottom cover (16) and a frame (14). The top cover faces the bottom cover. The frame is located between the top cover and bottom cover. The static electricity eliminating structure is in contact with the frame, which includes a main body (182) and a tin-cobalt alloy layer (184) formed on a surface of the main body.

### BACKGROUND OF THE INVENTION

1. Field of the Invention

The present invention generally relates to housings for portable electronic devices, and particularly to a housing for portable electronic device having a static electricity eliminating structure.

2. Discussion of the Related Art

In recent years, there has been an increase in demand for portable electronic devices, such as personal digital assistants (PDAs), mobile phones, MP3 players and MP4 players. Commonly, housings of the portable electronic devices are made of plastics. To improve appearance and durability of the portable electronic devices, some housings of the portable electronic devices may be made of metallic materials.

In some portable electronic devices such as mobile phones, the housings are made of aluminum alloy because of the alloy low density and aesthetic appearance. To prevent the housing from corrosion, an anodic oxidation coating is applied on the surface of the housing. However, the anodic oxidation coated housing exhibits lower conductivity and thus the discharge of static electricity will be limited, therefore other means of static discharge is required.

Generally, the housing of the portable electronic device includes a cover and a static electricity eliminating structure connected to the cover. In use, the static electricity eliminating structure can discharge the static electricity to the ground/earth through a user. Most configuration of the static electricity eliminating structure is complex, and the static electricity eliminating structure is made of aluminum alloy. To prevent the alloy from corrosion, the surface of the aluminum alloy is, also, treated. One method for surface treatment of the static electricity eliminating structure is to use zinc or nickel plating. However, the color of the zinc or nickel layer does not match to that of the aluminum alloy, thereby affecting the appearance of the portable electronic device.

Therefore, a new housing for portable electronic device is desired in order to overcome the above-described shortcomings.

### SUMMARY

A housing for portable electronic device includes a main structure and a static electricity eliminating structure. The static electricity eliminating structure is in contact with the main structure. The static electricity eliminating structure includes a main body and a tin-cobalt alloy layer formed on a surface of the main body.

Other novel features will become more apparent from the following detailed description, when taken in conjunction with the accompanying drawings.

### BRIEF DESCRIPTION OF THE DRAWINGS

The components in the drawings are not necessarily drawn to scale, the emphasis instead being placed upon clearly illustrating the principles of the present housing for portable electronic device. Moreover, in the drawings, like reference numerals designate corresponding parts throughout several views, and all the views are schematic.

FIG. 1 is an exploded view of a housing for portable electronic device in accordance with a preferred embodiment of the present invention.

FIG. 2 is an assembled, side, cross-sectional view of the housing for portable electronic device of FIG. 1.

### DETAILED DESCRIPTION OF THE EMBODIMENTS

Reference will now be made to the drawings to describe preferred embodiments of the present housing for portable electronic device in detail.

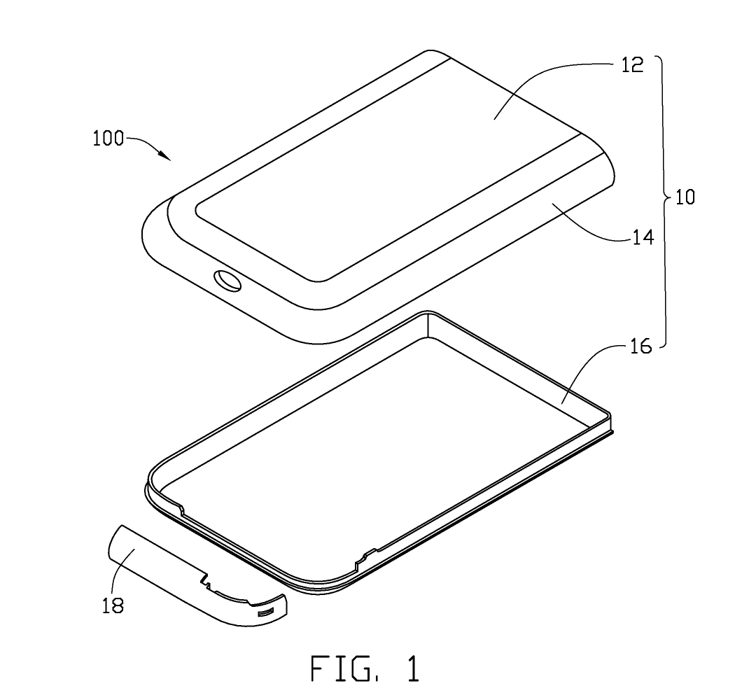

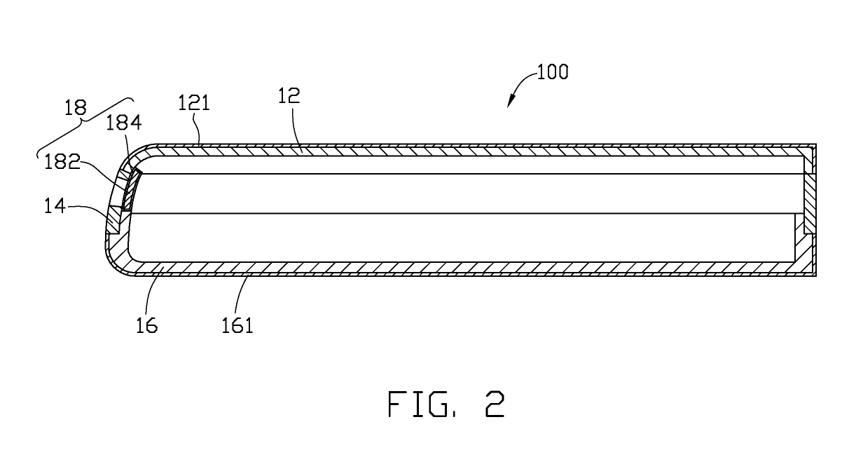

Referring to FIGS. 1 and 2, a housing 100 for a portable electronic device according to an embodiment is shown. The portable electronic device is a mobile phone for exemplary purposes, but may be other portable, or non-portable electronic devices. The housing 100 includes a main structure 10 and a static electricity eliminating structure 18. The static electricity eliminating structure 18 connects with the main structure 10. The static electricity eliminating structure 18 includes a main body 182, and a tin-cobalt alloy layer 184. The tin-cobalt alloy layer 184 is formed on a surface of the main body 182.

The main structure 10 is used to contain, fix, and protect a functional member of the portable electronic device. In the illustration embodiment, the main structure 10 includes a top cover 12, a frame 14, and a bottom cover 16. The top cover 12 is opposite to the bottom cover 16. The frame 14 is located between the top cover 12 and the bottom cover 16. A main composition material of the top cover 12 and the bottom cover 16 is aluminum alloy. A main composition material of the frame 14 is stainless steel. To prevent the top cover 12 and the bottom cover 16 from corrosion, a protection layer 121, 161 may be formed on the top cover 12 and the bottom cover 16 respectively. The protection layer 121, 161 can be a passivating layer, for example an anodic oxidation coating.

The static electricity eliminating structure 18 is configured to remove the static electricity generated by the portable electronic device. In this embodiment, the static electricity eliminating structure 18 is correspondingly in contact with the frame 14 of the main structure 10. A material of the main body 182 of the static electricity eliminating structure 18 can be magnesium alloy, and the main body 182 can be molded by die-casting. Thus the main body 182 has a light weight and a high strength, and the main body 182 is easily manufactured.

The tin-cobalt alloy layer 184 is formed on the surface of the main body 182. A material of the tin-cobalt alloy layer 184 includes, by weight, of the tin-cobalt alloy layer 184, tin in an amount from about 70% to about 90%, cobalt in an amount from about 10% to about 30%. The tin-cobalt alloy layer 184 can be prepared by plating. The tin-cobalt alloy layer 184 has a high degree of resistance to corrosion, thereby preventing the main body 182 from corrosion. The tin-cobalt alloy layer 184, also, has an improved performance of conductivity, therefore the static electricity can be easily discharged to the frames 14 by the static electricity eliminating structure 18, and then discharged to the ground/earth through a user. Further, the color of the tin-cobalt alloy layer 184 is similar to the color of the protection layer 121, 161, therefore the color of the static electricity eliminating structure 18 can blend in with that of the main structure 10, and thus the appearance of housing 100 for the portable electronic device can be improved. In addition, a raw material for the tin-cobalt alloy layer 184 is environment-friendly, therefore in the preparation of the tin-cobalt alloy layer 184, the environment is minimally affected.

It is noted that the scope of the present housing for a portable electronic device is not limited to the embodiments described above. In alternative embodiments, the portable electronic device can be a personal digital assistant, a MP3 player, or a MP4 player. The main composition material of the top cover 12 and the bottom cover 16 can be magnesium alloy or plastic. The main composition material of the frame 14 can also be other conductive material with corrosion resistance properties. If a portion of the static electricity eliminating structure 18 can directly come in contact with the user so that the user can discharge the static electricity, the frame 14 can also be made of insulated material.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A housing for portable electronic device, comprising:
a main structure; and
a static electricity eliminating structure in contact with the main structure, the static electricity eliminating structure comprising a main body and a tin-cobalt alloy layer formed on a surface of the main body.

2. The housing for portable electronic device as claimed in claim 1, wherein the main structure comprises a top cover, a bottom cover and a frame, the top cover and the bottom cover made of aluminum alloy or magnesium alloy, the frame made of stainless steel.

3. The housing for portable electronic device as claimed in claim 2, wherein each of the top cover and the bottom cover comprises a protection layer on a surface thereof.

4. The housing for portable electronic device as claimed in claim 3, wherein the protection layer is a passivating layer.

5. The housing for portable electronic device as claimed in claim 4, wherein the passivating layer is an anodic oxidation coating.

6. The housing for portable electronic device as claimed in claim 2, wherein the static electricity eliminating structure connects with the frame.

7. The housing for portable electronic device as claimed in claim 1, wherein a material of the main body is one of magnesium alloy and aluminum alloy.

8. The housing for portable electronic device as claimed in claim 1, wherein the tin-cobalt alloy layer comprises, by weight of the tin-cobalt alloy layer, tin in an amount from about 70% to about 90%, cobalt in an amount from about 10% to about 30%.

9. The housing for portable electronic device as claimed in claim 1, wherein the portable electronic device is one of personal digital assistant, mobile phone, MP3 player, and MP4 player.

10. A housing for portable electronic device, comprising:
a main structure having a top cover, a bottom cover and a frame, the top cover facing the bottom cover, the frame located between the top cover and bottom cover; and
a static electricity eliminating structure in contact with the frame, and the static electricity eliminating structure comprising a main body and a tin-cobalt alloy layer formed on a surface of the main body.

11. The housing for portable electronic device as claimed in claim 10, wherein each of the top cover and the bottom cover comprises a passivating layer at a surface thereof.

12. The housing for portable electronic device as claimed in claim 11, wherein the protection layer is a passivating layer.

13. The housing for portable electronic device as claimed in claim 12, wherein the passivating layer is an anodic oxidation coating.

14. The housing for portable electronic device as claimed in claim 10, wherein a main composition material of the top cover and the bottom cover is one of aluminum alloy, magnesium alloy, and plastic.

15. The housing for portable electronic device as claimed in claim 10, wherein a main composition material of the frame is stainless steel.

16. The housing for portable electronic device as claimed in claim 10, wherein a main composition material of the main body is one of magnesium alloy and aluminum alloy.

17. The housing for portable electronic device as claimed in claim 10, wherein the tin-cobalt alloy layer comprises, by weight of the tin-cobalt alloy layer, tin in an amount from about 70% to about 90%, cobalt in an amount from about 10% to about 30%.

18. The housing for portable electronic device as claimed in claim 10, wherein the portable electronic device is one of personal digital assistant, mobile phone, MP3 player, and MP4 player.
